(19) United States
(12) Patent Application Publication
(10) Pub. No.: US 2025/0202444 A1
(43) Pub. Date: Jun. 19, 2025

(54) AUTO-CALIBRATION DRIVING STRENGTH SYSTEM FOR CLASS-D AMPLIFIER

(71) Applicant: Nuvoton Technology Corporation, Hsinchu (TW)

(72) Inventors: Chang-Xian Wu, San Jose, CA (US); Bal Sandhu, San Jose, CA (US)

(21) Appl. No.: 18/544,362

(22) Filed: Dec. 18, 2023

(51) Int. Cl. H03F 3/217

(52) U.S. Cl. CPC H03F 3/217; H03F 2200/351

(57) ABSTRACT

A class-D amplifier includes a pulse width modulation (PWM) signal generator configured to generate an input signal, a p-type output transistor and an n-type output transistor connected in series with the p-type output transistor at an output terminal, and an output monitor connected to the output terminal and configured to detect a duty cycle of an output signal at the output terminal. The amplifier includes a pre-driver circuit having a first input terminal, a second input terminal, a first output terminal, and a second output terminal. The first input terminal is connected to the PWM signal generator to receive the input signal, the second input terminal is connected to the output monitor to receive the duty cycle, the first output terminal is connected to a gate of the p-type output transistor, and the second output terminal is connected to a gate of the n-type output transistor.

### FIELD

This invention relates to the field of electronic circuits in audio systems. More particularly, the present invention relates to auto-calibration control for class-D amplifier driver circuits.

### BACKGROUND

A class-D amplifier, also known as a switching amplifier, is an electronic amplifier in which transistors operate as binary switches. They are either fully on or fully off. Class-D amplifiers employ rail-to-rail output switching, where, ideally, their output transistors virtually always carry either zero current or zero voltage. Thus, their power dissipation is minimal, and they provide high efficiency over a wide range of power levels. Their advantageous high efficiency has propelled their use in various audio applications, from cell phones to flat screen televisions and home theater receivers. Class-D audio power amplifiers are more efficient than class-AB audio power amplifiers. Because of their greater efficiency, class-D amplifiers require smaller power supplies and eliminate heat sinks, thus significantly reducing overall system costs, size, and weight.

### BRIEF SUMMARY OF THE INVENTION

One general aspect includes a class-D amplifier. The class-D amplifier includes a pulse width modulation (PWM) signal generator configured to generate an input signal. The amplifier also includes a p-type output transistor. The amplifier also includes an n-type output transistor connected in series with the p-type output transistor at an output terminal. The amplifier also includes an output monitor connected to the output terminal and configured to detect a duty cycle of an output signal at the output terminal. The amplifier also includes a pre-driver circuit having a first input terminal, a second input terminal, a first output terminal, and a second output terminal. The first input terminal is connected to the PWM signal generator to receive the input signal, the second input terminal is connected to the output monitor to receive the duty cycle of the output signal, the first output terminal is connected to a gate of the p-type output transistor to provide a first gate voltage, and the second output terminal is connected to a gate of the n-type output transistor to provide a second gate voltage.

Implementations may include one or more of the following features. In some embodiments, the pre-driver circuit determines the first gate voltage and the second gate voltage based on the duty cycle of the output signal. In some embodiments, the first gate voltage and the second gate voltage are complementary to each other.

In some embodiments, in a first phase, the second gate voltage is at logic low, and the first gate voltage is at logic high.

In some embodiments, in a second phase, the second gate voltage increases to a first voltage level near a threshold voltage of the n-type output transistor. In some embodiments, the first voltage level deviates from the threshold voltage of the n-type output transistor by a value greater than or smaller than 200 mv. In some embodiments, the pre-driver circuit includes a slew rate controller activated in the second phase, and a slew rate of the class-d amplifier is adjusted in the second phase by the slew rate controller. In some embodiments, the slew rate controller may include a first current output digital-to-analog converter (DAC) connected between ground and the n-type output transistor, and an output current at an output terminal of the first current output DAC is adjusted based on the duty cycle of the output signal. In some embodiments, the output terminal is connected to a source of the n-type output transistor, and a gate-source voltage of the n-type output transistor is adjusted by the output current.

In some embodiments, in a third phase, the second gate voltage increases to a second voltage level higher than the first voltage level. In some embodiments, the n-type output transistor is fully turned on at the second voltage level. In some embodiments, the pre-driver circuit includes a bias voltage controller activated in the third phase, and a bias voltage of the n-type output transistor is adjusted in the third phase by the bias voltage controller. In some embodiments, the bias voltage controller may include a second current output DAC connected in series with a resistor, and an output current at an output terminal of the second current output DAC is adjusted based on the duty cycle of the output signal.

In some embodiments, the output monitor may include a duty cycle detector configured to detect the duty cycle. In some embodiments, the output monitor further may include a steady state detector, and the steady state detector is configured to sense the output signal at the output terminal and generate a current signal and compare the current signal to a reference current. In some embodiments, when the current signal is higher than a reference current, the slew rate controller is deactivated.

Another general aspect includes a method for operating a class-D amplifier. The method includes receiving, by a pulse width modulation (PWM) signal generator of the class-D amplifier, an input signal. The method also includes detecting, by an output monitor of the class-D amplifier, a duty cycle of an output signal at an output terminal of the class-D amplifier. The method also includes determining, by a pre-driver circuit of the class-D amplifier based on the duty cycle and the input signal, a first gate voltage applied to a gate of a p-type output transistor. The method also includes determining, by the pre-driver circuit of the class-D amplifier based on the duty cycle and the input signal, a second gate voltage applied to a gate of an n-type output transistor. The n-type output transistor is connected in series with the p-type output transistor at the output terminal. The method also includes applying the first gate voltage to the gate of the p-type output transistor. The method also includes applying the second gate voltage to the gate of the n-type output transistor.

Implementations may include one or more of the following features. In some embodiments, in a first phase, the second gate voltage is configured as logic low, and the first gate voltage is configured as logic high. In some embodiments, in a second phase, the second gate voltage is configured to increase to a first voltage level near a threshold voltage of the n-type output transistor. In some embodiments, in a third phase, the second gate voltage is configured to increase to a second voltage level higher than the first voltage level.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified schematic diagram illustrating a class-D amplifier 100, which is a conventional class-D amplifier.

FIG. 1B is a waveform diagram illustrating the modulation of signals in the class-D amplifier 100 of FIG. 1A.

FIG. 2 is a block diagram illustrating a class-D amplifier having an auto-calibration driver circuit in accordance with some embodiments.

FIG. 3 is a diagram illustrating the operation of the class-D amplifier 200 of FIG. 2 in accordance with some embodiments.

FIG. 4 is a diagram illustrating the relationship between the inductor current and the duty cycle at the output node in accordance with some embodiments.

FIG. 5 is a diagram illustrating the operation of the duty cycle detector in accordance with some embodiments.

FIG. 6 is a diagram illustrating an example of the steady state detector in accordance with some embodiments.

FIG. 7 is a diagram illustrating an example of the slew rate controller in accordance with some embodiments.

FIG. 8 is a diagram illustrating an example of the bias voltage controller in accordance with some embodiments.

FIG. 9 is a diagram illustrating the adaptive gate voltages of the class-D amplifier in accordance with some embodiments.

FIG. 10 is a diagram illustrating the voltages of gate terminals in different phases in accordance with some embodiments.

FIG. 11 is a flowchart diagram illustrating an example method for operating a class-D amplifier in accordance with some embodiments.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain (“S/D”) region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Class D audio power amplifiers convert audio input signal into high-frequency pulses that switch the output transistors in accordance with the audio input signal. Some class-D amplifiers use pulse width modulators (PWM) to generate a series of conditioning pulses that vary in width according to the amplitude of the audio input signal. The width-varying pulses switch the output transistors at a fixed frequency. Other class-D amplifiers may rely upon other types of pulse modulators. The following discussion will mainly refer to pulse width modulators, but a person of ordinary skill in the art will recognize that class-D amplifiers may be configured with other types of modulators.

As will be discussed in greater detail below, the present disclosure relates to improving the slew rate of the class-D amplifier during switching when the class-D amplifier employs rail-to-rail output voltage swing. Slew rate is the change of voltage (or current) per unit time. The unit of measurement is usually expressed in terms of, for example, volts per microseconds (V/μs). When given for the output of a class-D amplifier, the slew rate specification guarantees that the speed of the output signal transition will be at least the given minimum, or at most the given maximum. If these limits are violated, some error might occur, and correct operation is no longer guaranteed. As an example, when the input signal of the class-D amplifier is a square wave, the output signal is desired to be a corresponding square wave. However, the actual output signal is not an ideal square wave, and rising edges have a slew rate.

The techniques disclosed can minimize over-shoot and under-shoot, which degrade the power efficiency of the class-D amplifier. Typically, Class-D amplifiers provide a power efficiency over 90%. In order to keep the power efficiency as high as possible, the slew rate on the output transistor gate must be carefully controlled.

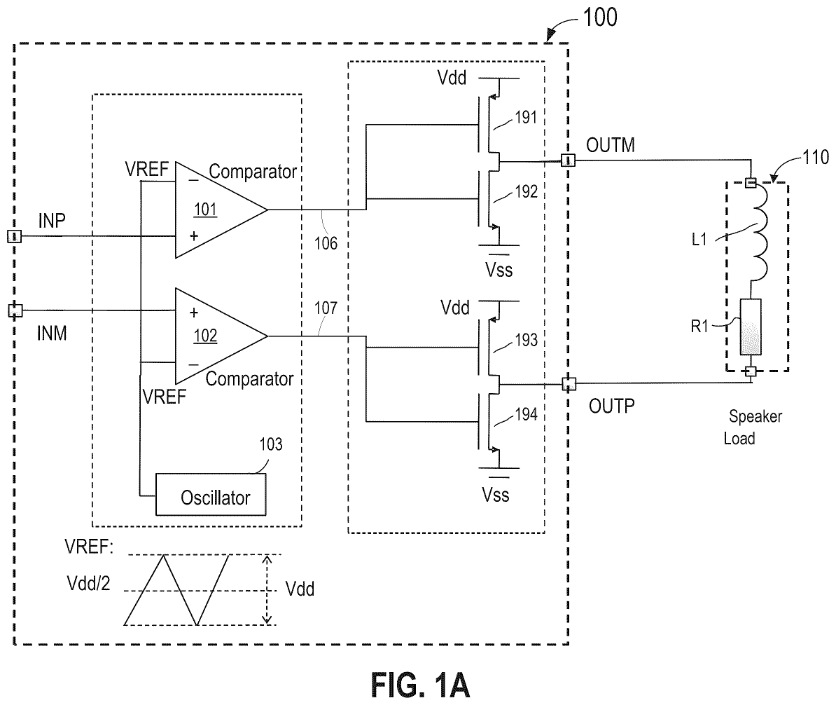

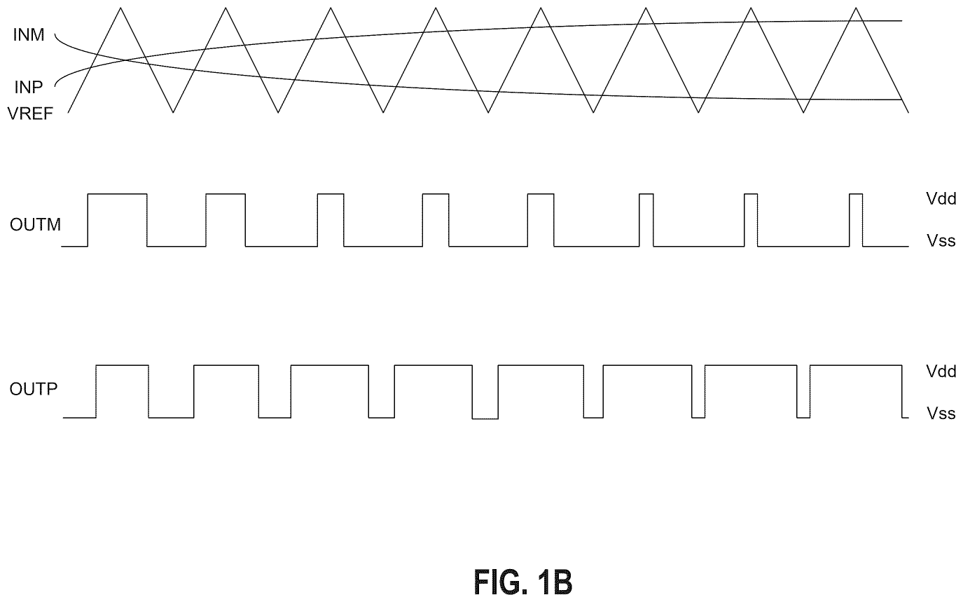

FIG. 1A is a simplified schematic diagram illustrating a class-D amplifier 100, which is a conventional class-D amplifier. As shown in FIG. 1A, the class-D amplifier 100 is a differential amplifier. A pair of differential audio input signals INP and INM (i.e., a first audio input signal INP and a second audio input signal INM) are input to a first comparator 101 and a second comparator 102, respectively. Each of the pair of differential audio input signals INP and INM is compared with a triangular signal (i.e., a signal having a triangular waveform) VREF generated from an oscillator 103 to generate a first PWM signal 106 and a second PWM signal 107, respectively. Since the first audio input signal INP and the second audio input signal INM are differential signals and the same triangular signal VREF is used as the reference signal, the first PWM signal and the second PWM signal 107 are differential signals as well (i.e., being the inverse of each other).

The first PWM signal 106 is coupled to the gates of output transistors 191 and 192, which are electrically connected together. The first PWM signal 106, therefore, controls the turning on and turning off of the output transistors 191 and 192. The second PWM signal 107 is coupled to the gates of output transistors 193 and 194, which are electrically connected together. The second PWM signal 107, therefore, controls the turning on and turning off the output transistors 193 and 194. As a result, the first output signal OUTM and the second output signal OUTP of the class-D amplifier 100 are differential output signals as well. As shown in FIG. 1A, the first output signal OUTM and the second output signal OUTP are applied to two ends of a speaker load 110, which is represented by an inductor L1 and a resistor R1 in FIG. 1A.

FIG. 1B is a waveform diagram illustrating the modulation of signals in the class-D amplifier 100 of FIG. 1A. As shown in FIG. 1B, the first audio input signal INP and the second audio input signal INM are compared with the triangular signal VREF, as described above in connection with FIG. 1A. The output signals of the first comparator 101 and the second comparator 102 are pulse signals at a fixed frequency (i.e., a fixed cycle) whose pulse width is proportional to its corresponding audio input signal. As a result, the first output signal OUTM and the second output signal OUTP are two PWM signals, as shown in FIG. 1B.

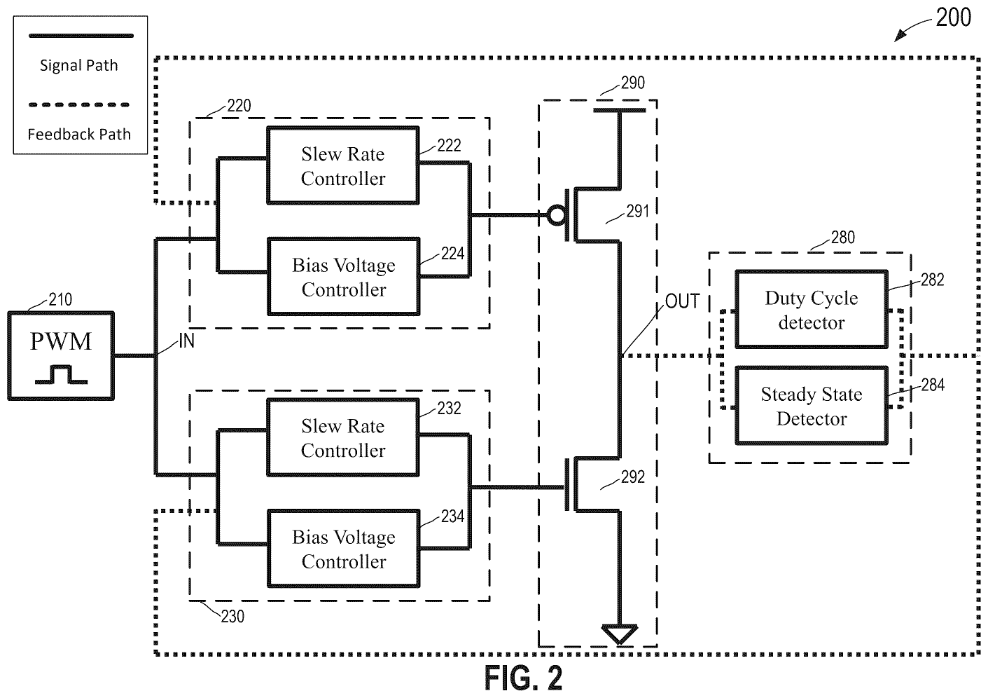

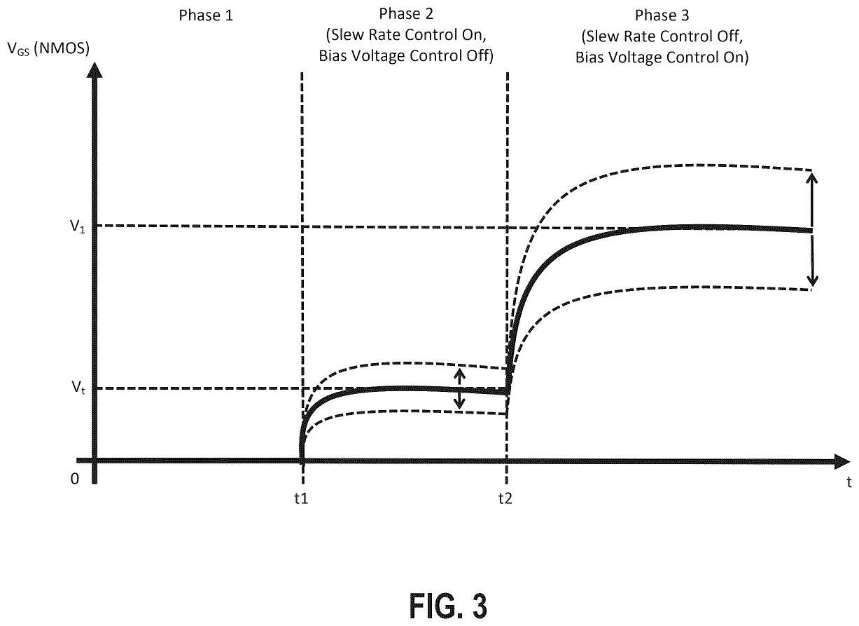

FIG. 2 is a block diagram illustrating a class-D amplifier 200 having an auto-calibration driver circuit in accordance with some embodiments. FIG. 3 is a diagram illustrating the operation of the class-D amplifier 200 of FIG. 2 in accordance with some embodiments.

In the example shown in FIG. 2, the output node (denoted as “OUT” in FIG. 2) of the class-D amplifier 200 is connected to an output load (e.g., a speaker load) 210, like the one shown in FIG. 1A, which is represented by an inductor L1 and a resistor R1.

In the example shown in FIG. 2, the class-D amplifier 200 includes, among other components, a PWM signal generator 210, a p-type pre-driver circuit 220, an n-type pre-driver circuit 230, a p-type output transistor 291, an n-type output transistor 292, and an output monitor 280.

The p-type output transistor 291 and the n-type output transistor 292 can be considered as the output stage 290. The p-type output transistor 291 and the n-type output transistor 292 are connected in series between a lower power rail (e.g., ground) and a higher power rail (e.g., V_{DD}). The p-type output transistor 291 and the n-type output transistor 292 are characterized by large dimensions (e.g., channel length, channel width, etc.), as compared to other transistors in the class-D amplifier 200, to drive the output load to meet the desired power efficiency. As a result, large parasitic capacitances are associated with the p-type output transistor 291 and the n-type output transistor 292, which will make the slew rate smaller (i.e., slowing down the slew rate). In one embodiment, the p-type output transistor 291 is a PMOS transistor, and the n-type output transistor 292 is an NMOS transistor. It should be understood that other types of transistors may be employed for the p-type output transistor 291 and the n-type output transistor 292. One of ordinary skill in the art would recognize many variations, modifications, and alternatives.

The PWM signal generator 210 generates an input signal at an input node (denoted as “IN” in FIG. 2). The PWM signal generator 210 may further generates an input bar signal, which is the complement of the input signal. In one implementation, the PWM signal generator 210 may include a comparator and an oscillator that generates a triangular wave, as discussed above in conjunction with FIGS. 1A and 1B. It should be understood that other architectures of PWM signal generators may be employed in other embodiments.

The p-type pre-driver circuit 220 and the n-type pre-driver circuit 230 can be considered as a pre-driver circuit connected between the PWM signal generator 210 and the output stage 290. In the example shown in FIG. 2, the p-type pre-driver circuit 220 includes, among other components, a p-type slew rate controller 222 and a p-type bias voltage controller 224, whereas the n-type pre-driver circuit 230 includes, among other components, an n-type slew rate controller 232 and an n-type bias voltage controller 234.

The p-type slew rate controller 222 receives the input signal generated by the PWM signal generator 210 and feedback signals generated by the output monitor 280 and controls the slew rate by adjusting the gate voltage of the p-type output transistor 291. Likewise, the n-type slew rate controller 232 receives the input signal generated by the PWM signal generator 210 and feedback signals generated by the output monitor 280 and controls the slew rate by adjusting the gate voltage of the n-type output transistor 292.

The p-type bias voltage controller 224 receives the input signal generated by the PWM signal generator 210 and feedback signals generated by the output monitor 280 and adaptively adjusts the bias voltage of the p-type output transistor 291. Likewise, the n-type bias voltage controller 234 receives the input signal generated by the PWM signal generator 210 and feedback signals generated by the output monitor 280 and adaptively adjusts the bias voltage of the n-type output transistor 292.

Details of the p-type pre-driver circuit 220 and the n-type pre-driver circuit 230 will be discussed below.

In the example shown in FIG. 2, the output monitor 280 includes, among other components, a duty cycle detector 282 and a steady state detector 284. The duty cycle detector 282 is configured to detect the duty cycle of the output signal at the output terminal OUT. The steady state detector 284 is configured to sense the output signal at the output terminal OUT and generates a current signal accordingly. The comparison between the current signal and a reference current results in indication of whether the class-D amplifier 200 is in a steady state. Details of the duty cycle detector 282 and the steady state detector 284 will be discussed below.

Details of the p-type pre-driver circuit 220 and the n-type pre-driver circuit 230 will be discussed below.

As shown in FIG. 2, there is a feedback path (denoted in dashed line in FIG. 2) from the output node OUT, thorough the output monitor 280, to the p-type pre-driver circuit 220. The output monitor 280 senses the output signal at the output node OUT, and generates feedback signals accordingly. There is a corresponding signal path from the PWM signal generator 210 to the p-type pre-driver circuit 220. The p-type pre-driver circuit 220 then adaptively adjusts the duty cycle and the bias voltage corresponding to the p-type output transistor 291.

As shown in FIG. 2, there is a feedback path (denoted in dashed line in FIG. 2) from the output node OUT, thorough the output monitor 280, to the n-type pre-driver circuit 230. The output monitor 280 senses the output signal at the output node OUT, and generates feedback signals accordingly. There is a corresponding signal path from the PWM signal generator 210 to the n-type pre-driver circuit 230. The p-type pre-driver circuit 220 then adaptively adjusts the duty cycle and the bias voltage corresponding to the n-type output transistor 292.

As shown in FIG. 3, the class-D amplifier 200 operates in three phases. Although FIG. 3 shows the gate-source voltage V_{GS} of the n-type output transistor 292, it should be understood that the same principles also apply to the p-type output transistor 291. The gate-source voltage V_{GS} of the p-type output transistor 291 is the complement of that of the n-type output transistor 292. When V_{GS} of the n-type output transistor 292 is logic low, Vs of the p-type output transistor 291 is logic high. When V_{GS} of the n-type output transistor 292 is logic high, V_{GS} of the p-type output transistor 291 is logic low.

In phase 1, V_{GS} of the n-type output transistor 292 is 0 V (i.e., logic low), and the n-type output transistor 292 is turned off. In the meantime, the p-type output transistor 291 is turned on.

In phase 2, V_{GS} of the n-type output transistor 292 increases to a level near the threshold voltage Vₜ of the n-type output transistor 292 (i.e., Vₜ±ΔV, wherein is the deviation, denoted by the dashed lines shown in FIG. 3). In one example, ΔV is 200 mV. It should be, ΔV may be other values in other embodiments. In other words, V_{GS} of the n-type output transistor 292 deviates from the threshold voltage Vₜ of the n-type output transistor 292 by a value ΔV. In one example, the value is 200 mV. In some examples, the value is smaller than 200 mv. In other examples, the value may be larger than 200 mV. As a result, the n-type output transistor 292 is soft turned on. In phase 2, the slew rate control is on (implemented by the n-type slew rate controller 232), while the bias voltage control is off (implemented by the n-type bias voltage controller 234). These implementations will be discussed in greater detail below.

In phase 3, V_{GS} of the n-type output transistor 292 further increases to a level near an elevated level V₁ higher than the threshold voltage Vₜ of the n-type output transistor 292. Similarly, the denoted dashed lines illustrate the range near the elevated level V₁. As a result, the n-type output transistor 292 is completely turned on. In phase 2, the slew rate control is off (implemented by the n-type slew rate controller 232), while the bias voltage control is on (implemented by the n-type bias voltage controller 234). These implementations will be discussed in greater detail below.

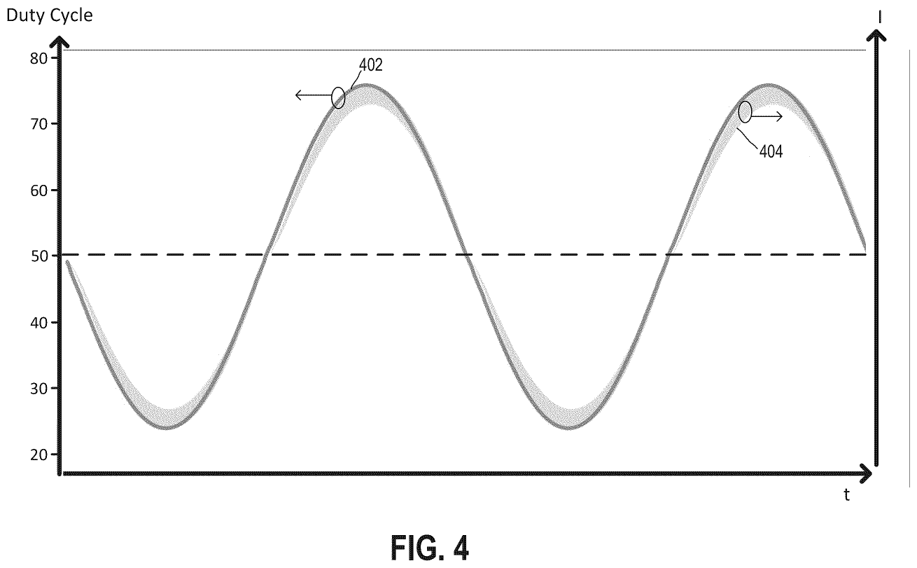

FIG. 4 is a diagram illustrating the relationship between the inductor current and the duty cycle at the output node in accordance with some embodiments. As shown in FIG. 4, the inductor current 404 tracks the duty cycle 402 of the output signal at the output terminal OUT, or vice versa. The inductor current 404 is the current sensed at the output terminal OUT and can be viewed, for example, as the current flowing through the inductor L1 of the speaker load 110 shown in FIG. 1A. When the inductor current 404 is zero (corresponding to the dashed line in the middle as shown in FIG. 4), the duty cycle 402 is 50%. As the inductor current 404 increases (from zero to the positive values above the dashed line shown in FIG. 4), the duty cycle 402 increases accordingly. As the inductor current 404 decreases (from zero to the negative values below the dashed line shown in FIG. 4), the duty cycle 402 decreases accordingly. Since the duty cycle 402 tracks the inductor current 404, the duty cycle 402 can be used to determine the inductor current 404. This is the principle of operation of the duty cycle detector 282.

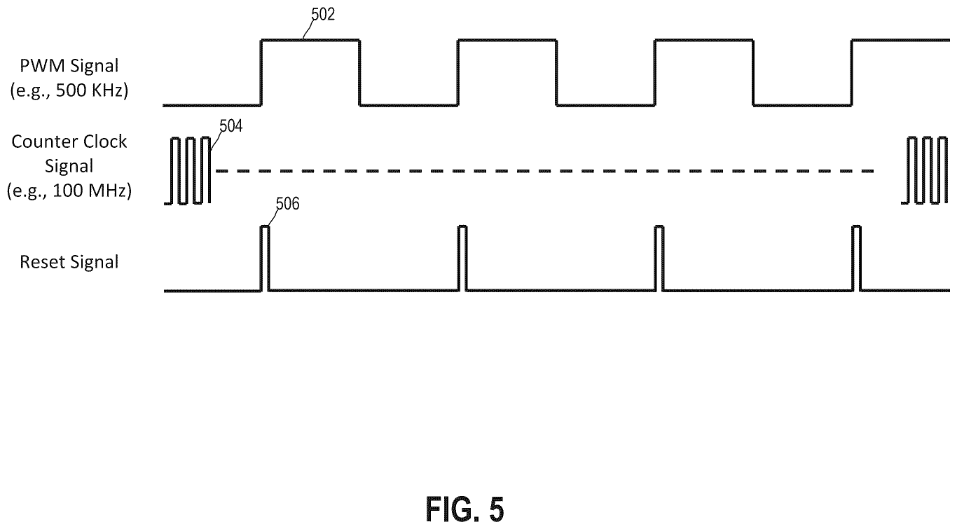

FIG. 5 is a diagram illustrating the operation of the duty cycle detector 282. In the example shown in FIG. 5, the output PWM signal 502 at the output terminal OUT is in the form of a pulse wave (i.e., a rectangular wave), and the frequency of the output PWM signal 502 is a first frequency (e.g., 500 KHz). The duty cycle detector 282 also includes a counter clock signal generator that generates a counter clock signal 504. In the example shown in FIG. 5, the frequency of the counter clock signal 504 is a second frequency (e.g., 100 MHz). The second frequency is higher than the first frequency. In this example, the second frequency is 200 times higher than the second first frequency. It should be noted that, other suitable frequencies can be chosen in other embodiments.

The duty cycle detector 282 counts the number of cycles of the counter clock signal 504 until the reset signal 506 toggles (i.e., a pulse of the reset signal 506 hits). The pulse of the reset signal 506 is aligned with the rising edge of the PWM signal 502. As a result, the duty cycle detector 282 counts the number of cycles of the counter clock signal 504 when the PWM signal 504 is at logic low. Accordingly, the duty cycle 402 is determined.

In the example shown in FIG. 5, when the count is 200, the duty cycle is 100%; when the count is 150, the duty cycle is 150%; when the count is 100, the duty cycle is 50%; when the count is 50, the duty cycle is 25%.

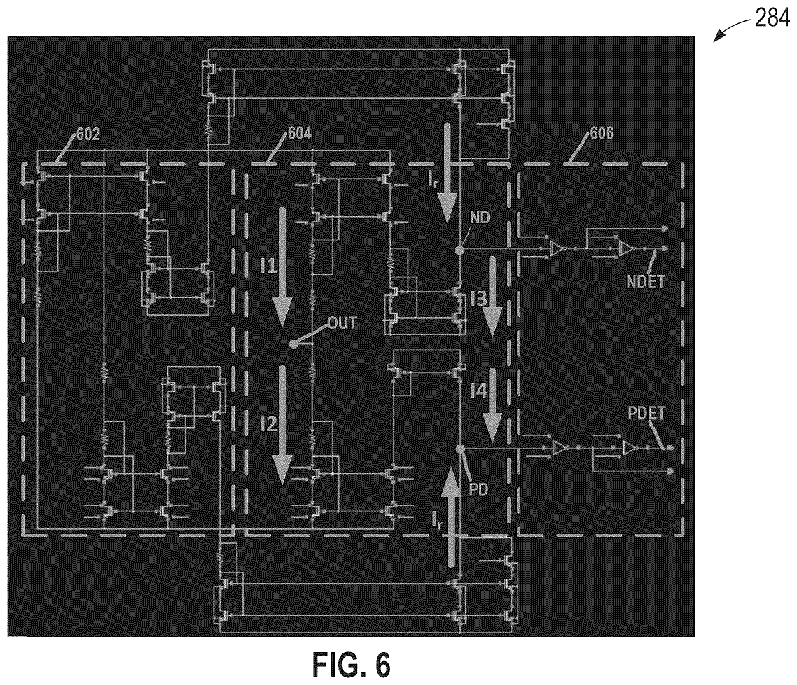

FIG. 6 is a diagram illustrating an example of the steady state detector 284 in accordance with some embodiments. In the example shown in FIG. 6, the steady state detector 284 includes, among other components, a current mirror 602, a detector circuit 604, and an output buffer 606. It should be understood that the example shown in FIG. 6 is not intended to be limiting, and the steady state detector 284 may have other structures in other embodiments.

The current mirror 602 is configured to set a reference current for the detector circuit 604. In some embodiments, the reference current follows the Vbst level, which is the maximum output voltage of the class-D amplifier 200. In one example, the Vbst level is about 12 V. It should be understood that this example is not intended to be limiting. In one example, the reference current is proportional to the Vbst level. In other words, the reference current varies as the Vbst level varies, and the ratio between them remains unchanged.

The detector circuit 604 is connected to the output terminal OUT shown in FIG. 2. The detector circuit 604 senses the output signal to generate a first input current I1 and/or a second input circuit I2 (based on the logic low or logic high of the output signal at the output terminal OUT), as shown in FIG. 6.

When the output signal at the output terminal OUT is logic low (i.e., “0”), a third current I3 is generated by the detector circuit 604 in response to the first input current I1. The third current I3 is proportional to the first input current I1. When the first input current I1 increases, the third current I3 increases accordingly.

At node ND shown in FIG. 6, the third current I3 is compared to the reference current Iᵣ generated by the current mirror 602. When the output signal at the output terminal OUT is logic low (i.e., “0”) and the third current I3 is larger than the reference current Iᵣ, the third current I3 pulls down the output signal, and the signal at the node NDET in the output buffer 606 becomes logic low (i.e., “0”). As will be discussed below, the signal at the node NDET is used to control (e.g., by way of an AND gate) the functioning of the n-type slew rate controller 232. When the third current I3 is larger than the reference current Iᵣ, indicating an unsteady state, the signal (i.e., logic low) at the node NDET deactivates the n-type slew rate controller 232.

Likewise, when the output signal at the output terminal OUT is logic high (i.e., “1”), a fourth current I4 is generated by the detector circuit 604 in response to the second input current I2. The fourth current I4 is proportional to the second input current I2. When the second input current I2 increases, the fourth current I4 increases accordingly.

At node PD shown in FIG. 6, the fourth current I4 is compared to the reference current Iᵣ generated by the current mirror 602. When the output signal at the output terminal OUT is logic high (i.e., “1”) and the fourth current I4 is larger than the reference current Iᵣ, the fourth current I4 pulls up the output signal, and the signal at the node PDET in the output buffer 606 becomes logic high (i.e., “1”).

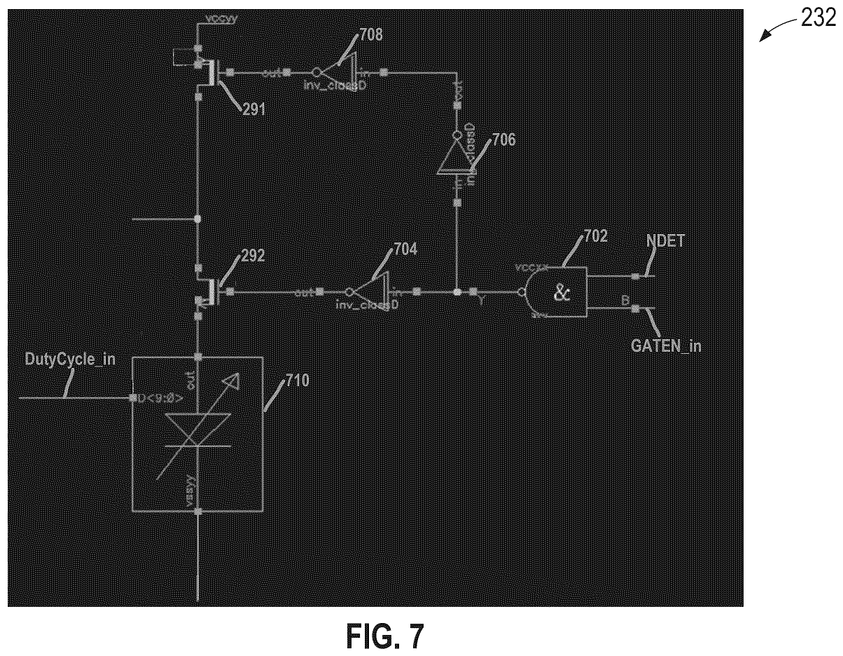

FIG. 7 is a diagram illustrating an example of the slew rate controller 232 in accordance with some embodiments. Although FIG. 7 shows an example of the n-type slew rate controller 232 shown in FIG. 2, the principles are also applicable to the p-type slew rate controller 222 shown in FIG. 2. In some embodiments, the p-type slew rate controller 222 is separate from the n-type slew rate controller 232. In other embodiments, the p-type slew rate controller 222 and the n-type slew rate controller 232 are integrated into one circuit.

In the example shown in FIG. 7, the n-type slew rate controller 232 includes, among other components, a current output digital-to-analog converter (DAC) 710. In some embodiments, the current output DAC 710 utilizes a binary weighted current ladder to develop the output current. A digital signal input, in binary format, is translated into a corresponding analog current output. In one implementation, the current output DAC 710 comprises a number of current branches (e.g., ten current branches), and each current branch includes an access transistor and a current generating transistor (in a common gate configuration). It should be understood that this is not intended to be limiting and other types of current output DAC may be employed in other embodiments. Since the current output DAC 710 is connected between the ground and the n-type output transistor 292, the fewer current branches are turned on, the higher V_{GS} of the n-type output transistor 292 becomes, and vice versa.

The current output DAC 710 has an input terminal (“DutyCycle_in” shown in FIG. 7). The output signal of, i.e., the duty cycle detected by, the duty cycle detector 282, is input to the input terminal of the current output DAC 710. As a result, the output current of the current output DAC 710 changes based on the duty cycle. The output current of the current output DAC 710 flows into the n-type output transistor 292. As the output current changes, the gate voltage of the n-type output transistor 292 changes accordingly, thereby adjusting the slew rate of the n-type output transistor 292.

When the inductor current becomes higher (e.g., in the positive direction), the duty cycle becomes larger (e.g., increases above 50%), as shown in FIG. 4. The duty cycle, by way of the current output DAC 710, changes the gate voltage of the n-type output transistor 292 accordingly (e.g., increases the gate voltage of the n-type output transistor 292 by having fewer current branches turned on), thereby adjusting the slew rate of the n-type output transistor 292. As shown in FIG. 3, the change of Vs of the n-type output transistor 292, near the threshold voltage Vₜ of the n-type output transistor 292, in phase 2 can achieve slew rate control.

In the example shown in FIG. 7, the n-type slew rate controller further includes a NAND gate 702, a first inverter 704, a second inverter 706, and a third inverter 708. A first input terminal (labeled as “GATEN_in” in FIG. 7) is configured to receive an n-type gate control signal that controls the switching of the n-type output transistor 292. A second input terminal is connected to the node NDET shown in FIG. 6. Therefore, the n-type gate control signal that controls the switching of the n-type output transistor 292 works only when the signal at node NDET is logic low (i.e., when the output signal at the output terminal OUT is logic low). The first inverter 704 and the combination of the second inverter 706 and the third inverter 708 generate complementary signals to control the n-type output transistor 292 and the p-type output transistor 291, respectively.

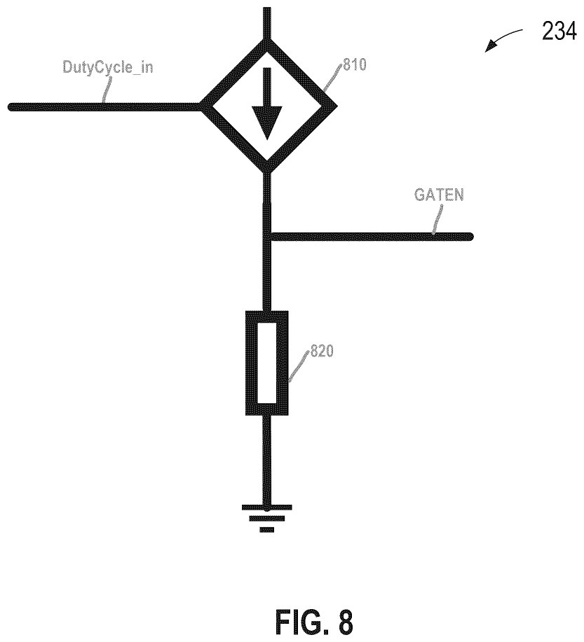

FIG. 8 is a diagram illustrating an example of the bias voltage controller in accordance with some embodiments. Although FIG. 8 shows an example of the n-type bias voltage controller 234 shown in FIG. 2, the principles are also applicable to the p-type bias voltage controller 224 shown in FIG. 2. In some embodiments, the p-type bias voltage controller 224 is separate from the n-type bias voltage controller 234. In other embodiments, the p-type bias voltage controller 224 and the n-type bias voltage controller 234 are integrated into one circuit.

In the example shown in FIG. 7, the n-type slew rate controller 232 includes, among other components, a current output DAC 810 and a resistor 820. The resistor 820 is connected between the current output DAC 810 and ground.

In some embodiments, the current output DAC 810 utilizes a binary weighted current ladder to develop the output current. A digital signal input, in binary format, is translated into a corresponding analog current output. In one implementation, the current output DAC 810 comprises a number of current branches (e.g., ten current branches), and each current branch includes an access transistor and a current generating transistor (in a common gate configuration). It should be understood that this is not intended to be limiting and other types of current output DAC may be employed in other embodiments. Since the resistor 820 is connected between the current output DAC 810 and ground, the fewer current branches are turned on, the lower the output voltage (at the terminal labeled as “GATEN”) of the n-type bias voltage controller 234 becomes. In other words, the output voltage at the terminal GATEN is controlled by the current output DAC 810 and the resistor 820.

The current output DAC 810 has an input terminal (“DutyCycle_in” shown in FIG. 8). The output signal of, i.e., the duty cycle detected by, the duty cycle detector 282, is input to the input terminal of the current output DAC 810. As a result, the output current of the current output DAC 810, and therefore the output voltage at terminal GATEN, changes based on the duty cycle. When the class-D amplifier 200 needs to deliver higher power, the output current of the current output DAC 810 becomes higher, the output voltage at terminal GATEN becomes higher accordingly, or vice versa. The output voltage at terminal GATEN determines V_{GS} of the n-type output transistor 292. As shown in FIG. 3, the change of V_{GS} of the n-type output transistor 292 in phase 3 can optimize the power efficiency automatically. As such, the bias voltage controller 234 and the bias voltage controller 224 can adaptively adjust V_{GS} of the n-type output transistor 292 in phase 3, depending on the power desired to be delivered.

Although one example is shown in FIG. 8, it should be understood that other configurations of the n-type bias voltage controller 234 may be employed in other embodiments. In one embodiment, an n-type bias voltage controller can include the n-type bias voltage controller 234 shown in FIG. 8 and a source follower circuit. The source follower circuit is connected to the node between the current output DAC 810 and the resistor 820 shown in FIG. 8. A source follower circuit, sometimes also referred to as a “common-drain amplifier,” is one of three basic single-stage FET amplifier topologies, typically used as a voltage buffer. The gate terminal of the transistor serves as the signal input, the source is the output, and the drain is common to both (input and output). The drive strength becomes larger by adding the source follower circuit.

In another embodiment, an n-type bias voltage controller can include the n-type bias voltage controller 234 shown in FIG. 8 and a unity gain buffer circuit. The unity gain buffer circuit is connected to the node between the current output DAC 810 and the resistor 820 shown in FIG. 8. A unity gain buffer (also called a unity-gain amplifier) is an operational amplifier (op-amp) circuit which has a voltage gain of 1. This means that the op-amp does not provide any amplification to the signal. The output voltage signal is the same as the input voltage. Since the op-amp circuit is a circuit with a very high input impedance, very little current is drawn from the circuit. As such, the power of the circuit isn't affected when current is feeding a high impedance load.

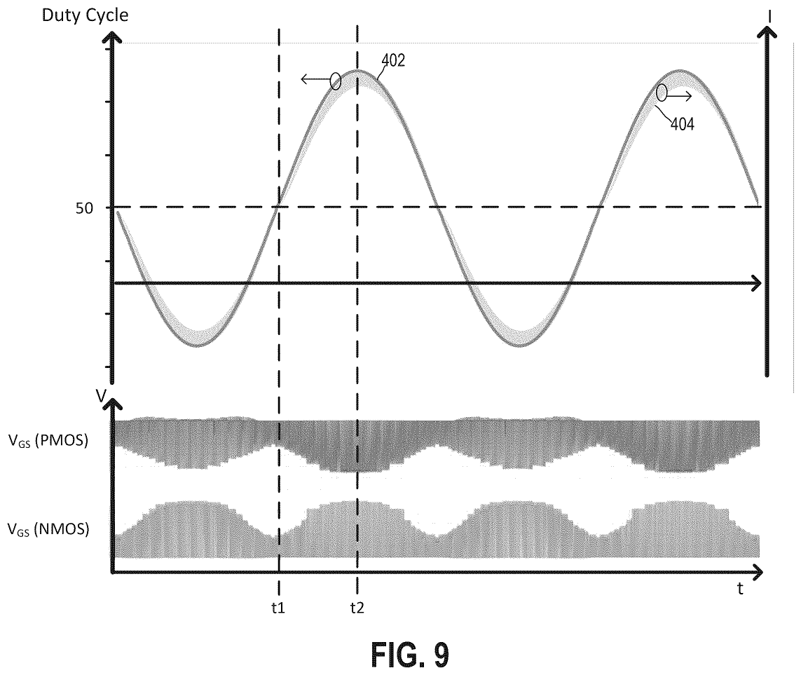

FIG. 9 is a diagram illustrating the adaptive gate voltages of the class-D amplifier in accordance with some embodiments. FIG. 9 shows the adaptive gate voltages as well as the duty cycle and inductor current, which are shown in FIG. 4. As shown in FIG. 9, when the duty cycle 402 is 50% (e.g., at time t1 shown in FIG. 9), the inductor current 404 is zero, as explained above with reference to FIG. 4. At this time t1, both the V_{GS} of the n-type output transistor 292 and the V_{GS} of the p-type output transistor 294 are at minimum values. When the duty cycle 402 increases to its peak (e.g., at time t2 shown in FIG. 9), the inductor current 404 reaches its peak accordingly, as explained above with reference to FIG. 4. At this time t2, both the V_{GS} of the n-type output transistor 292 and the V_{GS} of the p-type output transistor 294 are at maximum values. The n-type output transistor 292 and the p-type output transistor 294 are turned on more, corresponding to phase 3 shown in FIG. 3.

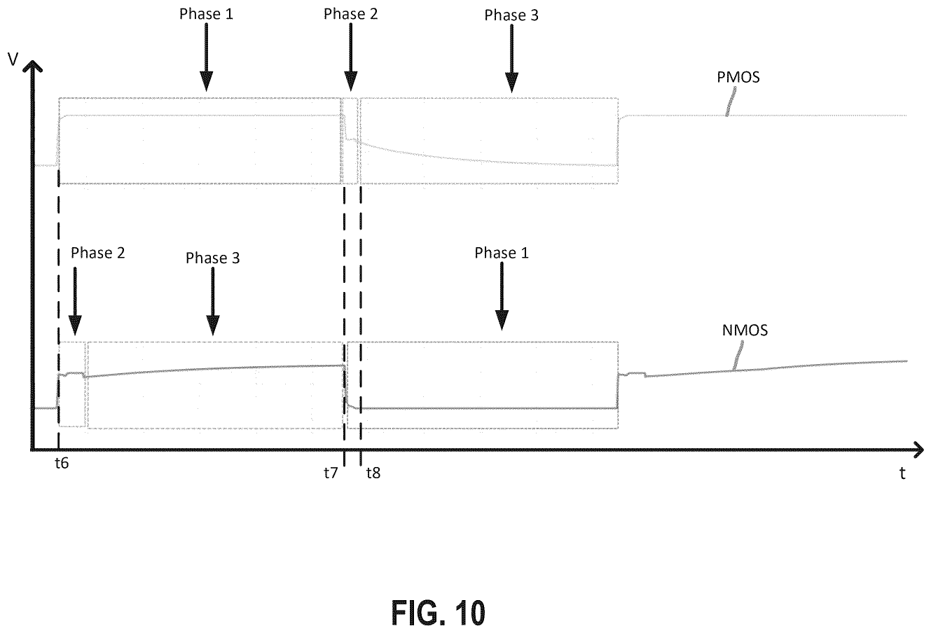

FIG. 10 is a diagram illustrating the voltages of gate terminals in different phases in accordance with some embodiments. The voltage of the gate terminal of the p-type output transistor 291 is in the upper half, whereas the voltage of the gate terminal of the n-type output transistor 292 is in the lower half. As shown in FIG. 10, when the p-type output transistor 291 transitions from phase 1 into phase 2 (e.g., t7 shown in FIG. 10), the voltage drops slightly, thereby being in the soft turned-on state in phase 2. In the meantime, the n-type output transistor 292 transitions from phase 3 into phase 1, the voltage drops fast, thereby being in the fully turned-off state in phase 1. At a later time (e.g., t8 shown in FIG. 10), the n-type output transistor 292 is still in phase 1, and the p-type output transistor 291 enters phase 3 as the p-type output transistor 291 is fully turned-on. This same timing happens as well when the n-type output transistor 292 transitions from phase 1 into phase 2 (e.g., t6 shown in FIG. 10), as shown in FIG. 10.

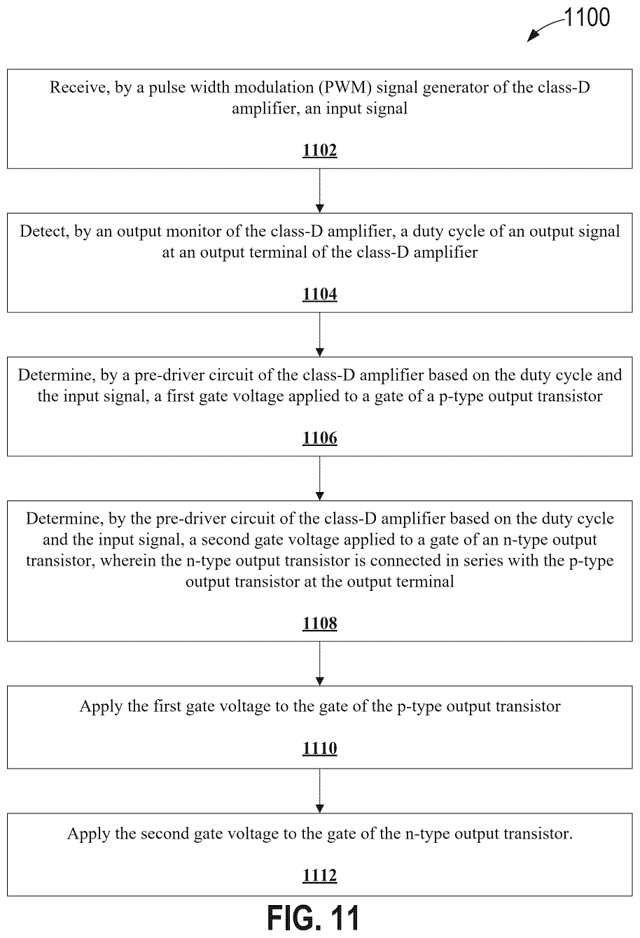

FIG. 11 is a flowchart diagram illustrating an example method for operating a class-D amplifier in accordance with some embodiments. In the example shown in FIG. 11, the method 1100 includes operations (or steps) 1102, 1104, 1106, 1108, 1110, and 1112. Additional operations may be performed. Also, it should be understood that the sequence of the various operations discussed above with reference to FIG. 11 is provided for illustrative purposes, and as such, other embodiments may utilize different sequences. For instance, steps 1106 and 1108 may be performed in a reverse order of that shown in FIG. 11 or simultaneously. These various sequences of operations are to be included within the scope of embodiments.

At step 1102, a pulse width modulation (PWM) signal generator (e.g., the PWM signal generator 210 shown in FIG. 2) of the class-D amplifier (e.g., the class-D amplifier 200 shown in FIG. 2) receives an input signal.

At step 1104, an output monitor (e.g., the output monitor 280 shown in FIG. 2) of the class-D amplifier detects a duty cycle of an output signal at an output terminal (e.g., OUT shown in FIG. 2) of the class-D amplifier.

At step 1106, a pre-driver circuit (e.g., the pre-driver circuits 220 and 230, collectively, shown in FIG. 2) of the class-D amplifier determines, based on the duty cycle and the input signal, a first gate voltage applied to a gate of a p-type output transistor (e.g., the p-type output transistor 291 shown in FIG. 2).

At step 1108, the pre-driver circuit of the class-D amplifier determines, based on the duty cycle and the input signal, a second gate voltage applied to a gate of an n-type output transistor (e.g., the n-type output transistor 292 shown in FIG. 2). The n-type output transistor is connected in series with the p-type output transistor at the output terminal.

At step 1110, the first gate voltage is applied to the gate of the p-type output transistor.

At step 1112, the second gate voltage is applied to the gate of the n-type output transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A class-D amplifier, comprising:
a pulse width modulation (PWM) signal generator configured to generate an input signal;
a p-type output transistor;
an n-type output transistor connected in series with the p-type output transistor at an output terminal;
an output monitor connected to the output terminal and configured to detect a duty cycle of an output signal at the output terminal; and
a pre-driver circuit having a first input terminal, a second input terminal, a first output terminal, and a second output terminal, wherein the first input terminal is connected to the PWM signal generator to receive the input signal, the second input terminal is connected to the output monitor to receive the duty cycle of the output signal, the first output terminal is connected to a gate of the p-type output transistor to provide a first gate voltage, and the second output terminal is connected to a gate of the n-type output transistor to provide a second gate voltage.

2. The class-D amplifier of claim 1, wherein the pre-driver circuit determines the first gate voltage and the second gate voltage based on the duty cycle of the output signal.

3. The class-D amplifier of claim 2, the first gate voltage and the second gate voltage are complementary to each other.

4. The class-D amplifier of claim 1, wherein in a first phase, the second gate voltage is at logic low, and the first gate voltage is at logic high.

5. The class-D amplifier of claim 4, wherein in a second phase, the second gate voltage increases to a first voltage level near a threshold voltage of the n-type output transistor.

6. The class-D amplifier of claim 5, wherein the first voltage level deviates from the threshold voltage of the n-type output transistor by a value greater than or smaller than 200 mV.

7. The class-D amplifier of claim 5, wherein the pre-driver circuit includes a slew rate controller activated in the second phase, and a slew rate of the class-D amplifier is adjusted in the second phase by the slew rate controller.

8. The class-D amplifier of claim 7, wherein the slew rate controller comprises a first current output digital-to-analog converter (DAC) connected between ground and the n-type output transistor, and an output current at an output terminal of the first current output DAC is adjusted based on the duty cycle of the output signal.

9. The class-D amplifier of claim 8, wherein the output terminal is connected to a source of the n-type output transistor, and a gate-source voltage of the n-type output transistor is adjusted by the output current.

10. The class-D amplifier of claim 5, wherein in a third phase, the second gate voltage increases to a second voltage level higher than the first voltage level.

11. The class-D amplifier of claim 10, wherein the n-type output transistor is fully turned on at the second voltage level.

12. The class-D amplifier of claim 10, wherein the pre-driver circuit includes a bias voltage controller activated in the third phase, and a bias voltage of the n-type output transistor is adjusted in the third phase by the bias voltage controller.

13. The class-D amplifier of claim 12, wherein the bias voltage controller comprises a second current output DAC connected in series with a resistor, and an output current at an output terminal of the second current output DAC is adjusted based on the duty cycle of the output signal.

14. The class-D amplifier of claim 1, wherein the output monitor comprises a duty cycle detector configured to detect the duty cycle.

15. The class-D amplifier of claim 14, wherein the output monitor further comprises a steady state detector, and the steady state detector is configured to sense the output signal at the output terminal and generate a current signal and compare the current signal to a reference current.

16. The class-D amplifier of claim 15, when the current signal is higher than a reference current, the slew rate controller is deactivated.

17. A method for operating a class-D amplifier, the method comprising:
receiving, by a pulse width modulation (PWM) signal generator of the class-D amplifier, an input signal;
detecting, by an output monitor of the class-D amplifier, a duty cycle of an output signal at an output terminal of the class-D amplifier;
determining, by a pre-driver circuit of the class-D amplifier based on the duty cycle and the input signal, a first gate voltage applied to a gate of a p-type output transistor;
determining, by the pre-driver circuit of the class-D amplifier based on the duty cycle and the input signal, a second gate voltage applied to a gate of an n-type output transistor, wherein the n-type output transistor is connected in series with the p-type output transistor at the output terminal;
applying the first gate voltage to the gate of the p-type output transistor; and
applying the second gate voltage to the gate of the n-type output transistor.

18. The method of claim 17, wherein in a first phase, the second gate voltage is configured as logic low, and the first gate voltage is configured as logic high.

19. The method of claim 18, wherein in a second phase, the second gate voltage is configured to increase to a first voltage level near a threshold voltage of the n-type output transistor.

20. The method of claim 19, wherein in a third phase, the second gate voltage is configured to increase to a second voltage level higher than the first voltage level.
